(19) United States
(12) Patent Application Publication
(10) Pub. No.: US 2014/0302995 A1
(43) Pub. Date: Oct. 9, 2014

(54) METHOD OF FORMING REWORKABLE, THERMALLY CONDUCTIVE AND ELECTRICALLY RESISTIVE BONDING STRUCTURE IN SUPERCONDUCTOR MULTI-CHIP MODULE USING REWORKABLE EPOXY BONDING COMPOSITES AND APPLICATION OF THE SAME

(71) Applicant: BOARD OF TRUSTEES OF THE UNIVERSITY OF ARKANSAS, Little Rock, AR (US)

(72) Inventors: Ajay P. Malshe, Springdale, AR (US); Vishwas N. Bedekar, Fayetteville, AR (US); Ranjith John, Midland, MI (US)

(73) Assignee: BOARD OF TRUSTEES OF THE UNIVERSITY OF ARKANSAS, Little Rock, AR (US)

(21) Appl. No.: 14/164,893

(22) Filed: Jan. 27, 2014

Related U.S. Application Data
(60) Provisional application No. 61/756,673, filed on Jan. 25, 2013.

(51) Int. Cl. H01L 39/24; H01L 39/22

(52) U.S. Cl. CPC H01L 39/2493; H01L 39/223
USPC 505/190; 505/329; 156/64; 428/414; 428/195.1

(57) ABSTRACT

In one aspect, the present invention relates to a method of forming a reworkable, thermally conductive and electrically resistive material as a bonding structure in a module and application of the same. In certain embodiments, a homogeneous solution is prepared with an anisotropic structure, such as single-wall carbon nanotubes (SWCNTs), and an epoxy resin. The homogeneous solution is applied between a carrier and a chip of the module, and cured at a curing temperature for a curing time period to form a reworkable epoxy bonding layer, which has an anisotropic structure loading factor of about 0.1%-1.0% such that the reworkable epoxy bonding layer is thermally conductive and electrically resistive. When the chip is identified as a faulty chip, the module may be heated at a debonding temperature for a debonding time period such that the reworkable epoxy bonding layer debonds, and the chip becomes detachable from the carrier.

### CROSS-REFERENCE TO RELATED PATENT APPLICATIONS

This application claims priority to and the benefit of, pursuant to 35 U.S.C. §119(e), U.S. provisional patent application Ser. No. 61/756,673, filed Jan. 25, 2013, entitled “REWORKABLE EPOXY BONDING AND THERMAL MANAGEMENT AND APPLICATIONS OF SAME,” by Ajay P. Malshe, Vishwas N. Bedekar and Ranjith John, the disclosure of which are incorporated herein in its entirety by reference.

Some references, which may include patents, patent applications and various publications, are cited and discussed in the description of this invention. The citation and/or discussion of such references is provided merely to clarify the description of the present invention and is not an admission that any such reference is “prior art” to the invention described herein. All references cited and discussed in this specification are incorporated herein by reference in their entireties and to the same extent as if each reference was individually incorporated by reference. In terms of notation, hereinafter, “[n]” represents the nth reference cited in the reference list. For example, [1] represents the 1st reference cited in the reference list, namely, Gupta, Deepnarayan, Kadin, Alan M., Mukhanov, Oleg A., Rosa, Jack, and Nicholson, David, “Benefits of Superconductor Digital-RF Transceiver Technology to Future Wireless Systems”, Proceedings of SDR Technical Conference, vol. 1, November 2002, pp 221-226.

### STATEMENT AS TO RIGHTS UNDER FEDERALLY-SPONSORED RESEARCH

This invention was made with government support under grant numbers STTR (Hypres) N00014-12-M-0389 and ONR N00014-12-1-0302, awarded by the Office of Naval Research (ONR). The government has certain rights in the invention.

### FIELD OF THE INVENTION

The present invention relates generally to reworkable epoxy bonding and thermal management, and more particularly to methods of applying reworkable, thermally conductive and electrically resistive bonding structures in a module, such as a superconductor multi-chip module, using reworkable epoxy bonding and application of the same.

### BACKGROUND OF THE INVENTION

Niobium based low-temperature (4K) superconducting electronics offer ultrafast switching speeds up to 100 GHz, with low power consumption[1-2]. The performance of these devices is through the technology based on the Josephson Effect and the fabrication of Josephson Junction (JJ) circuits. JJ circuits require ultra-low temperature of 4K (−269° C.) to be maintained to achieve the exceptional performance. This temperature requirement was viewed as a serious obstacle for the realization of user friendly cryogenic electronic systems. However, with the advent of commercial cryo-coolers user friendly high performance superconducting circuits have been realized. Namely, HYPRES Inc. has demonstrated the performance of these low temperature superconducting microelectronic devices in cryo-cooled systems [2]. Thus, there is a need to develop new material and packaging techniques that aid in the realization of ultrafast superconductor electronics in novel architectures.

Therefore, a heretofore unaddressed need exists in the art to address the aforementioned deficiencies and inadequacies.

### SUMMARY OF THE INVENTION

One aspect of the present invention relates to a method of applying a reworkable, thermally conductive and electrically resistive material as a bonding structure in a module with a carrier and at least one chip, which includes: (a) purifying an anisotropic structure; (b) dispersing the purified anisotropic structure in a solvent to form a mixture; (c) adding an epoxy resin in the mixture to form a anisotropic structure-epoxy solution; (d) forming a homogeneous mixture by heating and stirring the anisotropic structure-epoxy solution for a first time period to evaporate the solvent; (e) cooling the homogeneous mixture at room temperature for a second time period, and adding a hardener in the cooled homogeneous mixture to form a homogeneous solution; (f) applying the homogeneous solution between the carrier and the chip of the module, and curing the homogeneous solution at a curing temperature for a curing time period to form a reworkable epoxy bonding layer between the carrier and the chip such that the chip is attached to the carrier by the reworkable epoxy bonding layer, where a CNT loading factor of the reworkable epoxy bonding layer is about 0.1%-1.0% such that the reworkable epoxy bonding layer is thermally conductive and electrically resistive, and where the reworkable epoxy bonding layer is configured to debond at a debonding temperature for a debonding time period such that the chip is detachable from the carrier; and (g) when the chip is identified as a faulty chip, detaching the faulty chip from the carrier by heating the module at the debonding temperature for the debonding time period, and performing a cleaning procedure to the detached chip and the detached carrier to reduce residues of the reworkable epoxy bonding layer on the detached chip and the detached carrier, such that a replacement chip is attachable to the carrier to replace the faulty chip, where the debonding temperature is about 63-170° C., and the debonding time period is about 1-25 minutes.

In certain embodiments, the anisotropic structure includes carbon nanotubes (CNTs). In certain embodiments, the CNTs are single-wall CNTs (SWCNTs).

In certain embodiments, the first time period is about 3-5 hours, the second time period is about 1.5-2.5 hours, the curing temperature is a room temperature, and the curing time period is about 20-28 hours.

In certain embodiments, the anisotropic structure loading factor of the reworkable epoxy bonding layer is about 0.6%-0.9%, the debonding temperature is about 65-90° C., and the debonding time period is about 1-6 minutes.

In certain embodiments, the anisotropic structure loading factor of the reworkable epoxy bonding layer is about 0.3%-0.5%, the debonding temperature is about 105-155° C., and the debonding time period is about 1-12 minutes.

In certain embodiments, the anisotropic structure includes a two dimensional (2D) anisotropic structure. In certain embodiments, the 2D anisotropic structure includes graphene.

In certain embodiments, the cleaning procedure includes: ultrasonicating the detached chip and the detached carrier in an acrylic remover for a third time period; and surface cleaning the detached chip and the detached carrier with acetone and isopropanol. In certain embodiments, the acrylic remover is Dynasolve. In certain embodiments, the cleaning procedure further includes: ultrasonicating the detached chip and the detached carrier in acetone for a fourth time period. In certain embodiments, the third time period is about 24-72 hours, and the fourth time period is about 24-48 hours.

In certain embodiments, the module is a superconductor multi-chip module. In certain embodiments, the superconductor multi-chip module includes the carrier and a plurality of chips, where each of the plurality of chips is configured to be attached to the carrier by a corresponding layer of the reworkable epoxy bonding layer.

In another aspect of the present invention, a method of applying a reworkable, thermally conductive and electrically resistive material as a bonding structure in a module with a carrier and at least one chip is disclosed. In certain embodiments, the method includes: (i) preparing a homogeneous solution with an anisotropic structure and an epoxy resin; (ii) applying the homogeneous solution between the carrier and the chip of the module, and curing the homogeneous solution at a curing temperature for a curing time period to form a reworkable epoxy bonding layer between the carrier and the chip such that the chip is attached to the carrier by the reworkable epoxy bonding layer, where an anisotropic structure loading factor of the reworkable epoxy bonding layer is about 0.1%-1.0% such that the reworkable epoxy bonding layer is thermally conductive and electrically resistive, and where the reworkable epoxy bonding layer is configured to debond at a debonding temperature for a debonding time period such that the chip is detachable from the carrier; and (iii) when the chip is identified as a faulty chip, detaching the faulty chip from the carrier by heating the module at the debonding temperature for the debonding time period, such that a replacement chip is attachable to the carrier to replace the faulty chip.

In certain embodiments, the step of preparing a homogeneous solution includes: (a) purifying the anisotropic structure; (b) dispersing the purified anisotropic structure in a solvent to form a mixture; (c) adding the epoxy resin in the mixture to form an anisotropic structure-epoxy solution; (d) forming a homogeneous mixture by heating and stirring the anisotropic structure-epoxy solution for a first time period to evaporate the solvent; and (e) cooling the homogeneous mixture at room temperature for a second time period, and adding a hardener in the cooled homogeneous mixture to form the homogeneous solution. In certain embodiments, the first time period is about 3-5 hours, and the second time period is about 1.5-2.5 hours.

In certain embodiments, the anisotropic structure includes carbon nanotubes (CNTs). In certain embodiments, the CNTs are single-wall CNTs (SWCNTs).

In certain embodiments, the curing temperature is a room temperature, and the curing time period is about 20-28 hours.

In certain embodiments, the anisotropic structure includes a two dimensional (2D) anisotropic structure. In certain embodiments, the 2D anisotropic structure includes graphene.

In certain embodiments, the debonding temperature is about 63-170° C., and the debonding time period is about 1-25 minutes.

In certain embodiments, the anisotropic structure loading factor of the reworkable epoxy bonding layer is about 0.6%-0.9%, the debonding temperature is about 65-90° C., and the debonding time period is about 1-6 minutes.

In certain embodiments, the anisotropic structure loading factor of the reworkable epoxy bonding layer is about 0.3%-0.5%, the debonding temperature is about 105-155° C., and the debonding time period is about 1-12 minutes.

In certain embodiments, the step of detaching the faulty chip when the chip is identified as the faulty chip further includes: performing a cleaning procedure to the detached chip and the detached carrier to reduce residues of the reworkable epoxy bonding layer on the detached chip and the detached carrier.

In certain embodiments, the cleaning procedure includes: ultrasonicating the detached chip and the detached carrier in an acrylic remover for a third time period; and surface cleaning the detached chip and the detached carrier with acetone and isopropanol. In certain embodiments, the acrylic remover is Dynasolve. In certain embodiments, the cleaning procedure further includes: ultrasonicating the detached chip and the detached carrier in acetone for a fourth time period. In certain embodiments, the third time period is about 24-72 hours, and the fourth time period is about 24-48 hours.

In certain embodiments, the module is a superconductor multi-chip module which includes the carrier and a plurality of chips, where each of the plurality of chips is configured to be attached to the carrier by a corresponding layer of the reworkable epoxy bonding layer.

Certain aspects of the present invention relate to reworkable modules formed by the method as disclosed above. In certain embodiments, the reworkable module may be a superconductor multi-chip module which includes the carrier and a plurality of chips, where each of the plurality of chips is configured to be attached to the carrier by a corresponding layer of the reworkable epoxy bonding layer.

These and other aspects of the present invention will become apparent from the following description of the preferred embodiment taken in conjunction with the following drawings, although variations and modifications therein may be affected without departing from the spirit and scope of the novel concepts of the disclosure.

### BRIEF DESCRIPTION OF THE DRAWINGS

The accompanying drawings illustrate one or more embodiments of the invention and together with the written description, serve to explain the principles of the invention. Wherever possible, the same reference numbers are used throughout the drawings to refer to the same or like elements of an embodiment.

FIG. 1A shows a flowchart of forming a reworkable epoxy bonding structure according to certain embodiments of the present invention.

FIG. 1B shows a flowchart of forming a homogeneous solution with single-wall carbon nanotubes and an epoxy resin according to certain embodiments of the present invention.

FIG. 1C shows a flowchart of a cleaning procedure for the detached chip and the detached carrier according to certain embodiments of the present invention.

FIG. 2 shows schematically the relationship of adhesion strength to CNT loading factor of reworkable epoxy bonding composites according to certain embodiments of the present invention.

FIG. 3 shows schematically the relationship of temperature gradient to applied power of epoxy bonding composites according to certain embodiments of the present invention.

FIG. 4 shows schematically the relationship of an average debonding temperature to CNT loading factor of reworkable epoxy bonding composites according to certain embodiments of the present invention.

FIG. 5 shows schematically the relationship of an average resistance to CNT loading factor of reworkable epoxy bonding composites according to certain embodiments of the present invention.

FIG. 6 shows schematically (a) an image of a sample of bonded carrier and chip, and (b) debonded images of the carrier and the chip according to certain embodiments of the present invention, where the CNT loading factor of the reworkable epoxy bonding composite is 0.1%.

FIG. 7 shows schematically (a) an image of a sample of bonded carrier and chip, and (b) debonded images of the carrier and the chip according to certain embodiments of the present invention, where the CNT loading factor of the reworkable epoxy bonding composite is 0.3%.

FIG. 8 shows schematically (a) an image of a sample of bonded carrier and chip, and (b) debonded images of the carrier and the chip according to certain embodiments of the present invention, where the CNT loading factor of the reworkable epoxy bonding composite is 0.5%.

FIG. 9 shows schematically (a) an image of a sample of bonded carrier and chip, and (b) debonded images of the carrier and the chip according to certain embodiments of the present invention, where the CNT loading factor of the reworkable epoxy bonding composite is 0.4%.

FIG. 10 shows schematically (a) an image of a sample of bonded carrier and chip, and (b) debonded images of the carrier and the chip according to certain embodiments of the present invention, where the CNT loading factor of the reworkable epoxy bonding composite is 0.6%.

FIG. 11 shows schematically (a) an image of a sample of bonded carrier and chip, and (b) debonded images of the carrier and the chip according to certain embodiments of the present invention, where the CNT loading factor of the reworkable epoxy bonding composite is 0.7%.

FIG. 12 shows schematically (a) an image of a detached carrier and chip sample before performing the cleaning protocol 1 and (b) an image of the detached carrier and chip sample after performing the cleaning protocol 1 according to certain embodiments of the present invention.

FIG. 13 shows schematically (a) an image of a detached carrier and chip sample before performing the cleaning protocol 2 and (b) an image of the detached carrier and chip sample after performing the cleaning protocol 2 according to certain embodiments of the present invention.

FIG. 14 shows schematically (a) an image of a detached carrier and chip sample before performing the cleaning protocol 3 and (b) an image of the detached carrier and chip sample after performing the cleaning protocol 3 according to certain embodiments of the present invention.

### DETAILED DESCRIPTION OF THE INVENTION

The present invention is more particularly described in the following examples that are intended as illustrative only since numerous modifications and variations therein will be apparent to those skilled in the art. Various embodiments of the invention are now described in detail. Referring to the drawings, like numbers indicate like components throughout the views. As used in the description herein and throughout the claims that follow, the meaning of “a”, “an”, and “the” includes plural reference unless the context clearly dictates otherwise. Also, as used in the description herein and throughout the claims that follow, the meaning of “in” includes “in” and “on” unless the context clearly dictates otherwise. Moreover, titles or subtitles may be used in the specification for the convenience of a reader, which shall have no influence on the scope of the present invention. Additionally, some terms used in this specification are more specifically defined below.

### DEFINITIONS

The terms used in this specification generally have their ordinary meanings in the art, within the context of the invention, and in the specific context where each term is used. Certain terms that are used to describe the invention are discussed below, or elsewhere in the specification, to provide additional guidance to the practitioner regarding the description of the invention. For convenience, certain terms may be highlighted, for example using italics and/or quotation marks. The use of highlighting has no influence on the scope and meaning of a term; the scope and meaning of a term is the same, in the same context, whether or not it is highlighted. It will be appreciated that same thing can be said in more than one way. Consequently, alternative language and synonyms may be used for any one or more of the terms discussed herein, nor is any special significance to be placed upon whether or not a term is elaborated or discussed herein. Synonyms for certain terms are provided. A recital of one or more synonyms does not exclude the use of other synonyms. The use of examples anywhere in this specification including examples of any terms discussed herein is illustrative only, and in no way limits the scope and meaning of the invention or of any exemplified term. Likewise, the invention is not limited to various embodiments given in this specification.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

As used herein, “around”, “about” or “approximately” shall generally mean within 20 percent, preferably within 10 percent, and more preferably within 5 percent of a given value or range. Numerical quantities given herein are approximate, meaning that the term “around”, “about” or “approximately” can be inferred if not expressly stated.

As used herein, “plurality” means two or more.

As used herein, the terms “comprising”, “including”, “carrying”, “having”, “containing”, “involving”, and the like are to be understood to be open-ended, i.e., to mean including but not limited to.

The term “loading factor” as used herein, refers to a weight ratio of a material. In other words, the “anisotropic structure loading factor” of an adhesive layer refers to the ratio of the weight of the anisotropic structure contained in the adhesive layer to the weight of the adhesive layer. When the anisotropic structure includes carbon nanotubes (CNTs), the CNT loading factor of an adhesive layer refers to the weight ratio of the CNTs contained in the adhesive layer to the adhesive layer.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

### OVERVIEW OF THE INVENTION

As the commercialization of low temperature superconducting microelectronic (LSCE) devices takes a turn towards miniaturization while increasing the functional density, there is a need to demonstrate the performance of these ultrafast circuits in a novel multi-chip module (MCM) architecture. The signature of MCM architecture is in the unique assembly of complementary functional chips, electrical routings and passive devices on a desired substrate. This could place impediments on the thermal management requirement for the performance of LSCE devices. Specifically, the higher density of heat to be removed per unit volume and the restricted access through which to remove it presents obstacles in the realization of a commercial low temperature superconducting microelectronic MCM systems. Thus a need exists to develop new material and packaging techniques that aid in the realization of ultrafast superconductor electronics in a novel MCM architecture.

Aspects of the present invention relates methods of forming reworkable epoxy bonding structures, such as superconductor multi-chip modules, using reworkable epoxy bonding composites and application of the same.

In certain embodiments, carbon nanotubes (CNT) and/or similar nano- and micro-structured anisotropic materials are used as additives to epoxy polymers to form a reworkable epoxy bonding composite, e.g. a polymer adhesive, which allows thermal reworkability to material network. The reworkable epoxy bonding composite will also provide thermally conducting and electrically insulating characteristics for effective thermal management, for example of superconducting electronics. Such reworkable epoxy bonding composite could be used for applications such as attaching device chips to a carrier substrate, sealing of helium fuel tank and fixing their leakage, etc. In certain embodiments, cleaning and reapplying process protocols for reworked surface are provided.

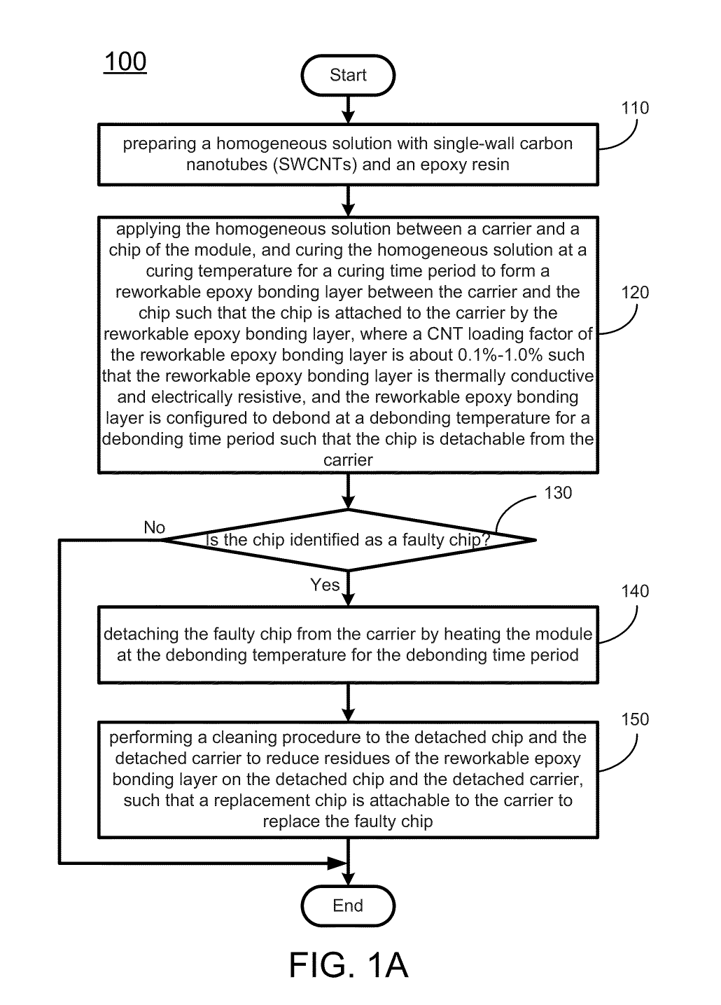

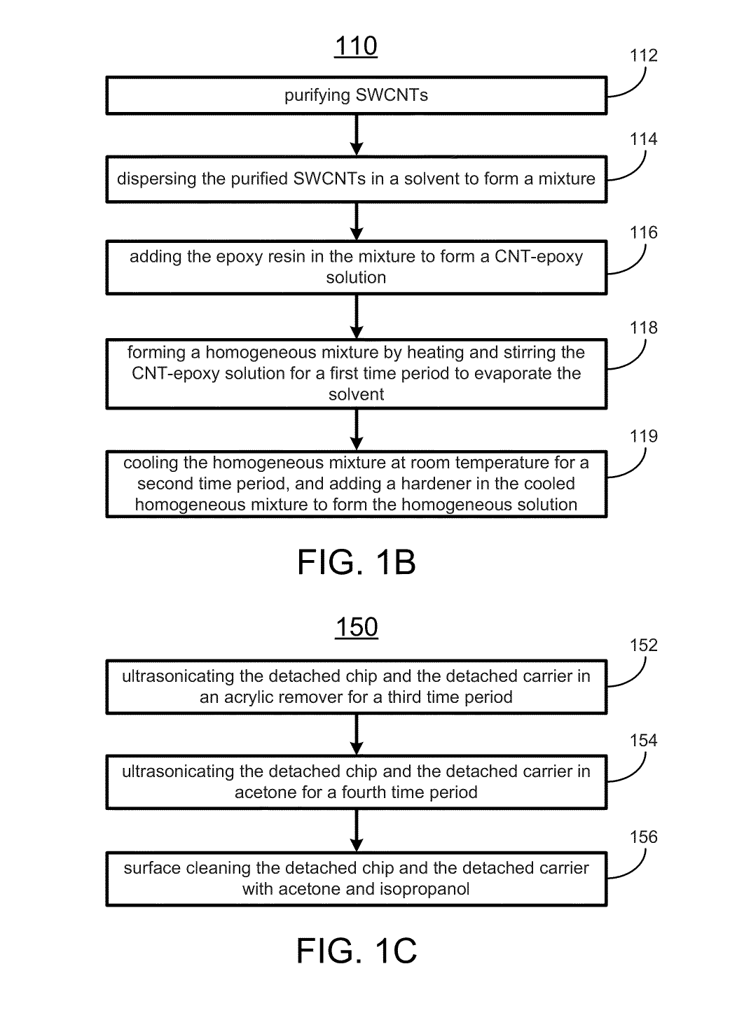

FIG. 1A shows a flowchart of forming a reworkable epoxy bonding structure according to certain embodiments of the present invention. In certain embodiments, the reworkable epoxy bonding structure is a reworkable module, which may be a superconductor multi-chip module having a carrier and a plurality of chips. Each of the chips may be an integrated circuit (IC), and the carrier may be a substrate or a board, such as a printed circuit board (PCB), for supporting the chips. Each of the chips is configured to be attached to the carrier by a corresponding layer of the reworkable epoxy bonding layer. In certain embodiments, the reworkable epoxy bonding structure may be formed by a carrier and one of the chips attached to the carrier by the reworkable epoxy bonding layer.

As shown in FIG. 1A, at step 110, a homogeneous solution with an anisotropic structure, such as single-wall CNTs (SWCNTs), and an epoxy resin is prepared as the base material of the reworkable epoxy bonding layer. In certain embodiments, the anisotropic structure may be two-dimensional (2D) anisotropic materials such as graphene, or three-dimensional (3D) anisotropic materials such as CNTs or other nanostructures.

At step 120, the homogeneous solution is applied as an underfill to fill in the gap between the carrier and the chip of the reworkable epoxy bonding module, and the underfill (the homogeneous solution) is then cured at a curing temperature for a curing time period to form a reworkable epoxy bonding layer between the carrier and the chip such that the chip is attached to the carrier by the reworkable epoxy bonding layer. The material of the reworkable epoxy bonding layer is a reworkable epoxy bonding composite formed by curing of the homogeneous solution. In certain embodiments, an anisotropic structure loading factor (i.e., the weight ratio of the anisotropic structure) of the reworkable epoxy bonding layer is about 0.1%-1.0% such that the reworkable epoxy bonding layer is thermally conductive and electrically resistive. Further, the reworkable epoxy bonding layer is configured to debond at a debonding temperature for a debonding time period such that the chip may be detachable from the carrier. In certain embodiments, the debonding temperature is about 63-170° C., and the debonding time period is about 1-25 minutes. In certain embodiments, the curing temperature may be the room temperature, and the curing time period may be about 20-28 hours.

At step 130, the chip of the reworkable epoxy bonding module is detected to identify if the chip is a normal chip or a faulty chip. The chip may be a faulty chip due to damage of the chip, or due to undesired adhering or positioning of the chip on the carrier.

When the chip is identified as a faulty chip, at step 140, the faulty chip may be detached from the carrier by heating the reworkable epoxy bonding module at the debonding temperature for the debonding time period. In certain embodiments, the debonding temperature is about 63-170° C., and the debonding time period is about 1-25 minutes.

In certain embodiments, after the faulty chip is detached from the carrier, at step 150, a cleaning procedure may be performed to the detached chip and the detached carrier to reduce residues of the reworkable epoxy bonding layer on the detached chip and the detached carrier, such that a replacement chip may be re-attachable to the carrier to replace the faulty chip. In certain embodiments, when the detached faulty chip is a damaged chip, the detached damaged chip may be discarded, and a replacement chip may be provided to replace the damaged chip. In certain embodiments, when the faulty chip is due to undesired adhering or positioning, the detached faulty chip may be reused after the cleaning procedure as the replacement chip, and a new chip is not necessary.

FIG. 1B shows a flowchart of forming a homogeneous solution with single-wall carbon nanotubes and an epoxy resin according to certain embodiments of the present invention. Specifically, FIG. 1B shows the detailed steps of forming the homogenous solution with the SWCNTs and the epoxy resin as described in step 110. It should be noted that other anisotropic structures may be used to replace the SWCNTs. For example, the 2D anisotropic material such as graphene may be used as the anisotropic structure to form the homogeneous solution.

At step 112, the SWCNTs are purified. Specifically, commercially purchased SWCNTs are generally produced in unpurified forms, and the purifying procedure is performed to ensure that an accurate CNT loading factor (i.e. the weight ratio of the CNT) in the reworkable epoxy bonding composite, which is used as the materials of the reworkable epoxy bonding layer, may be achieved.

At step 114, the purified SWCNTs are dispersed in a solvent to form a mixture. In certain embodiments, the solvent may be Isopropanol (IPA). The dispersing of the purified SWCNTs may be performed by sonication and stirring.

At step 116, the epoxy resin is added in the mixture to form a CNT-epoxy solution. The epoxy resin serves as the base adhesive of the reworkable epoxy bonding composite, and may be commercial purchased epoxy resin.

At step 118, a homogeneous mixture is formed by heating and stirring the CNT-epoxy solution for a first time period to evaporate the solvent. In certain embodiments, when IPA is used as the solvent, the first time period may be about 3-5 hours for all of the IPA to be evaporated.

At step 119, the homogeneous mixture is cooled at room temperature for a second time period, and a hardener is added in the cooled homogeneous mixture to form the homogeneous solution. In certain embodiments, the second time period may be about 1.5-2.5 hours

FIG. 1C shows a flowchart of a cleaning procedure for the detached chip and the detached carrier according to certain embodiments of the present invention. Specifically, FIG. 1C shows the detailed steps of the cleaning procedure for the detached chip and the detached carrier as described in step 150.

At step 152, the detached chip and the detached carrier are ultrasonicated in an acrylic remover for a third time period. In certain embodiments, Dynasolve may be used as the acrylic remover, and the third time period may be about 24-72 hours.

At step 154, the detached chip and the detached carrier are ultrasonicated in acetone for a fourth time period. In certain embodiments, the fourth time period may be about 24-48 hours.

At step 156, a surface cleaning process is performed to the detached chip and the detached carrier with acetone and IPA.

It should be appreciated that the steps as shown in FIG. 1C are presented only for the purposes of illustration of the cleaning procedure, and the sequence of the steps may be subject to change.

In certain embodiments, the CNT loading factor of the reworkable epoxy bonding layer may be about 0.6%-0.9%. In this case, the debonding temperature may be about 65-90° C., and the debonding time period may be about 1-6 minutes.

In certain embodiments, the CNT loading factor of the reworkable epoxy bonding layer may be about 0.3%-0.5%. In this case, the debonding temperature may be about 105-155° C., and the debonding time period may be about 1-12 minutes.

These and other aspects of the present invention are more specifically described below.

### IMPLEMENTATIONS AND EXAMPLES OF THE INVENTION

Without intent to limit the scope of the invention, exemplary methods and their related results according to the embodiments of the present invention are given below. Note that titles or subtitles may be used in the examples for convenience of a reader, which in no way should limit the scope of the invention. Moreover, certain theories are proposed and disclosed herein; however, in no way they, whether they are right or wrong, should limit the scope of the invention so long as the invention is practiced according to the invention without regard for any particular theory or scheme of action.

One aspect of the present invention relates to a method of applying a reworkable, thermally conductive and electrically resistive material as a bonding structure in a module, such as a superconductor multi-chip module, using reworkable epoxy bonding composites.

Based on the method, the inventors have performed experiments to create flip chip bonded package samples, and performed tests on the samples to identify the reworkability of the reworkable epoxy bonding composites. Certain factors of the reworkability may include the CNT loading factor (i.e. the weight ratio of the SWCNTs) of the reworkable epoxy bonding composites, the adhesion strength, and the temperature gradient.

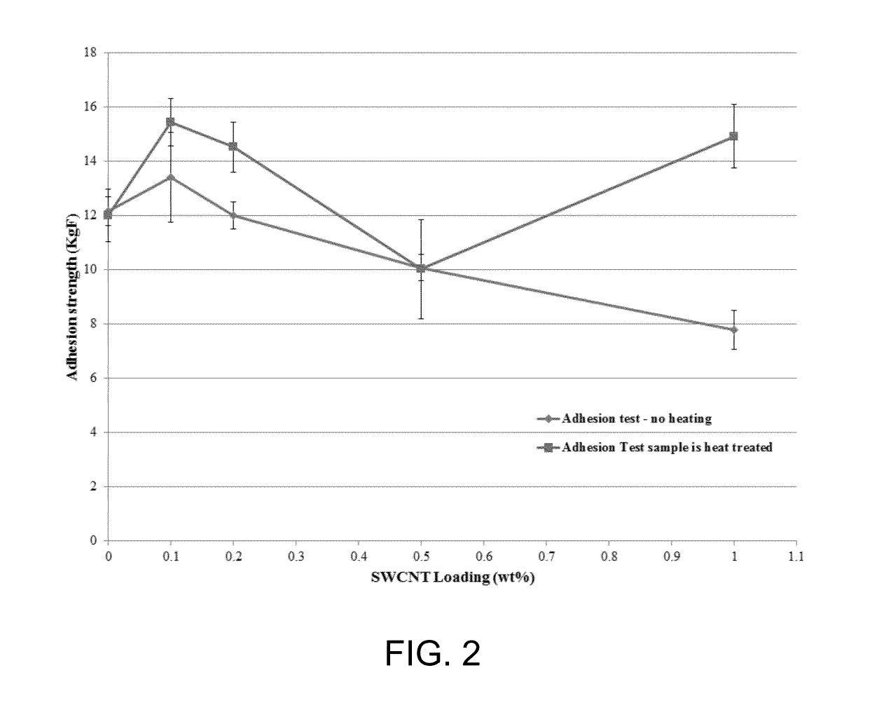

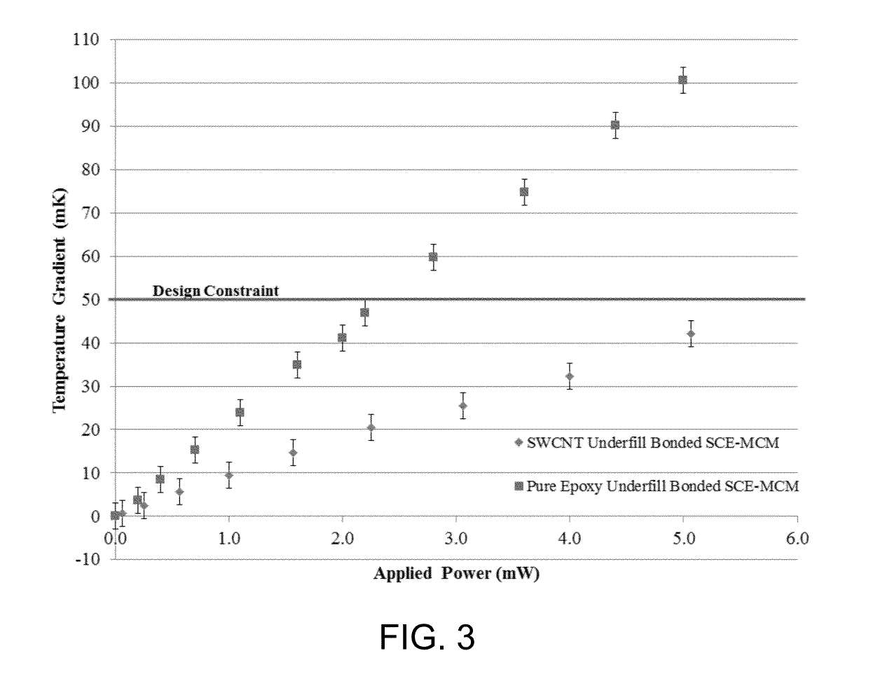

FIG. 2 shows schematically the relationship of adhesion strength to CNT loading factor of reworkable epoxy bonding composites according to certain embodiments of the present invention, and FIG. 3 shows schematically the relationship of temperature gradient to applied power of epoxy bonding composites according to certain embodiments of the present invention.

As shown in FIG. 2, the CNT loading factor of the reworkable epoxy bonding composites refers to the nanoparticle loading of the SWCNTs, which reduces the crosslinking density of the composites, and results in lowering of the adhesion strength of the composites. As shown in FIG. 3, a design constraint of 50 mK threshold of the temperature gradient is applied. The temperature gradient between a SCE chip and a SCE carrier is significantly higher than the 50 mK threshold when flip chip bonded package is formed using thermo-compression bonding. Further, reduction in temperature gradient may be achieved using pure cryogenic underfill and capillary flow bonding. A thermally conducting and electrically insulating SWCNT underfill is developed for cryogenic packaging. The SWCNT underfill may be integrated in an active SCE-MCM. FIG. 3 shows that, comparing to superconducting electronics (SCE) multi-chip modules (MCMs) using pure epoxy underfills, the temperature gradient of the SCE-MCMs was reduced to below than the 50 mK threshold using SWCNT-loaded epoxy underfills.

The purpose of using an underfill is to provide mechanical support to the flip chip bonded package by filling the gap between the chip (e.g., an IC) and the carrier (e.g., a substrate or a board). As discussed above, reworkability of the underfill is desired when a faulty chip has been identified and needs to be moved from the carrier and replaced with a new chip. In certain embodiments, the reworking process may involve two steps: heating the package assembly until reflow of the solder bumps occur, and heating the package assembly until the underfill becomes flexible. In certain embodiments, the two steps may be then followed by cleaning of the underfill and flux from the carrier using a solvent.

Thus, the inventors has performed thermal, electrical and mechanical tests for bare wafer pairs using reworkable epoxy bonding composites, and performed electrical characterization of carrier-chip pairs with circuits. Each test is conducted with 10 chips for the purpose of narrowing the reproducibility of reworkability to temperature and time. Further, continuity tests are performed at the room temperature for attachment, detachment and measurement of electrical properties (resistances). Moreover, a series of cleaning processes/protocols of cleaning to determine the amount of residue accumulation on the carrier.

As used herein, the term “reworkability” refers to capability of a material that may be reused. For example, a reworkable epoxy bonding composite may be used as a polymer adhesive in a superconductor module to attach a chip (e.g., an IC) to the carrier (e.g., the substrate or the board). In a component level, the reworkability of the reworkable epoxy bonding composite refers to processing the reworkable epoxy bonding composite to debond and re-bond the chip to the carrier to form a chip bonded package. In certain embodiments, the reworkability may refer to the process of heating and debonding of the reworkable epoxy bonding composite such that the chip attached to the carrier by the reworkable epoxy bonding layer becomes detachable, and the detached chip and the detached carrier may be cleaned and then reused for functional applications. The reworkability of the reworkable epoxy bonding composite may be determined by the debonding temperature, at which the interface material of the polymer adhesive debonds and partfly reflows such that the chip may be detached from the carrier, and the debonding time of the reworkable epoxy bonding composite.

The reworkability of the reworkable epoxy bonding composite is due to integration of the SWCNTs in the epoxy base material. The SWCNT integration in the epoxy base material is expected to modify the glass transition temperature (T_{G}) and the crosslinking density of the adhesive, which in turn lowers the rework temperature (i.e. the debonding temperature) of the adhesive. Further, the SWCNT fillers decrease the rework temperature by creating a coefficient of thermal expansion (CTE) mismatch in the composite matrix. Moreover, the difference of in thermal conductivity is also expected to cause hot spots at the SWCNT-polymer interface, leading to a lower rework temperature.

### Experiments

Based on the above descriptions, the inventors have performed experiments to acquire statistical data for the repeatability and reliability parameter matrix. The debonding temperature and the debonding time serve as a function of the CNT loading factor of the reworkable epoxy bonding composite. The performance matrix of the experiments include CNT loading factor, thermal measurements, electrical measurements, inspection of epoxy removal process, and the measurement of material properties, which are listed in Table 1. For each performance matrix, a minimum of 5 samples are tested, and the minimum number of 10-15 tests are performed.

TABLE 1
Reworkabillity - Performance Matrix

| | | Min. No. | Min. |
|---|---|---|---|
| Performance | | of Samples | No. |
| Matrix | Measurement/Property | tested | of Tests |
| CNT loading | 0.1%-1.0% CNT | 5 | 10 |
| factor | | | |
| Thermal | Debonding temperature and time | 5 | 10 |
| Measurements | | | |
| Electrical | Resistance from carrier pads - | 5 | 10-15 |
| Measurements | continuity check | | |
| Inspection | Amount of residue accumulated | 5 | 10-15 |
| of Epoxy | on the carrier | | |
| Removal | | | |
| Process | | | |
| Measurement | Performance variation or | 5 | 10-15 |
| of material | degradation of carrier | | |
| properties | | | |

For experiment purposes, the base adhesive is commercially purchased (Trabond 2115, Henkel Inc.) and SWCNTs produced by the high pressure decomposition of carbon monoxide (HiPCO) method (Unidym, Batch R0556) were obtained in unpurified form and purified as described [3]. Thermo-gravimetric analysis (TGA) of unpurified SWCNT indicated that the SWCNT material contained 26 wt % impurities and upon purification the amount of impurities was reduced to less than 6 wt %. Transmission electron microscopy (TEM) and TGA analysis were completed to verify the same.

Purified SWCNT was dispersed uniformly in IPA via sonication and stirring. The base resin was added to the mixture and stirred on a hot plate until all of the IPA was evaporated. A smooth emulsion indicated a homogenous dispersion of nanotubes in resin. The hardener was added and the samples were dispensed between two blocks of oxygen free high conductivity copper (OFHC). The nanocomposite was cured according the curing schedule (65° C. for 2 hours) of base epoxy and left at room temperature for a day. The preparing of the materials has been described in the flowcharts of FIGS. 1A-1C.

### Thermal Reworkability Tests

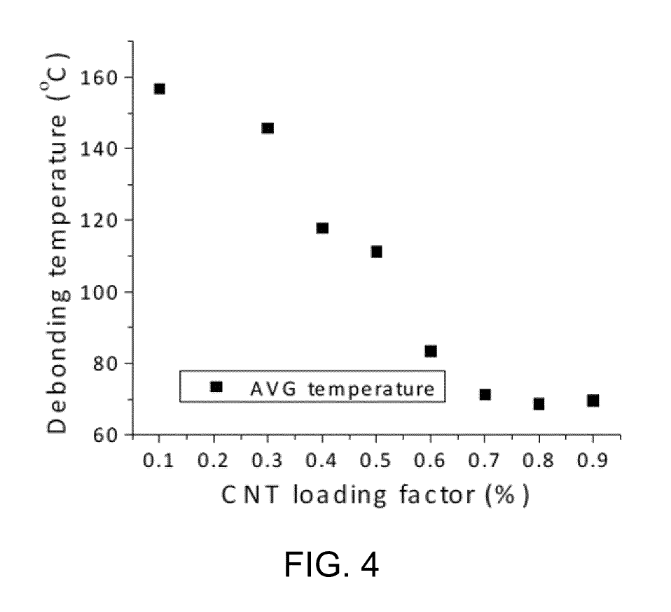

FIG. 4 shows schematically the relationship of an average debonding temperature to CNT loading factor of reworkable epoxy bonding composites according to certain embodiments of the present invention. Data of the average debonding temperature as shown in FIG. 4 is obtained by the statistical data acquired in the thermal reworkability tests, which is listed in Table 2. As shown in FIG. 4 and Table 2, when the CNT loading factor increased, the reworkable temperature decreased, resulting in the average debonding temperature decreased. For example, the samples with 0.7% CNT loading factor was debonded at an average debonding temperature of 71.23° C. in 5 minutes.

TABLE 2
Thermal Reworkability Tests

| | | Detachment | |
|---|---|---|---|
| CNT loading factor | | Temperature (° C.) | Detachment Time |
| (%) | Sample | [±5° C.] | (min) [±10 sec] |
| 0.1 | 1 | 165 | 2 |
| 0.1 | 2 | 155 | 10 |
| 0.1 | 3 | 150 | 25 |
| 0.3 | 1 | 151 | 1 |
| 0.3 | 2 | 144 | 2 |
| 0.3 | 3 | 142 | 2 |
| 0.5 | 1 | 111.4 | 5 |
| 0.5 | 2 | 112.2 | 5 |
| 0.5 | 3 | 110.2 | 5 |
| 0.4 | 1 | 116 | 10 |
| 0.4 | 2 | 118.4 | 10 |
| 0.4 | 3 | 119 | 12 |
| 0.6 | 1 | 80.2 | 4 |
| 0.6 | 2 | 85.2 | 2 |
| 0.6 | 3 | 84.4 | 2 |
| 0.7 | 1 | 70.7 | 5 |
| 0.7 | 2 | 72.5 | 5 |
| 0.7 | 3 | 70.5 | 4 |

### Reworkability Tests

A plurality of reworkability tests is performed with the following steps. A sample of a carrier and chip pair is bonded with a CNT-epoxy ratio. The sample is then debonded to measure the debonding temperature and time. A cleaning process is performed to the carrier using the cleaning protocol 2, which will be described later. A sample of the cleaned old carrier and a new chip pair is then re-bonded with a new CNT-epoxy ratio. The sample is then debonded to measure the debonding temperature and time. The data acquired by the tests is listed in Table 3.

TABLE 3
Reworkability Tests

| | | Debonding | | Debonding |
|---|---|---|---|---|
| | CNT | Temperature | | Temperature |
| Sample | ratio (%) | and Time | CNT ratio (%) | and Time |
| 1 | 0.5 | 111° C.; 5 min | 0.9 | 73.5° C.; 2 min |
| 2 | 0.3 | 140° C.; 5 min | 0.7 | 72.8° C.; 2 min |
| 3 | 0.5 | 112.5° C.; 5 min | 0.7 | 73° C.; 5 min |

### Thermal Cycling Tests

A plurality of thermal cycling tests is performed with the following steps. A sample of a carrier and chip pair is bonded with a selected CNT-epoxy ratio. The sample is then performed with thermal cycling setup with a defined procedure of a temperature range and a soak time. After the thermal cycling procedure, the sample is then debonded to measure the debonding temperature and time. The data acquired by the tests is listed in Table 4. As shown in Table 4, no measurable degradation was found in the thermal performance of the epoxy composite undergoing the thermal cycling tests.

TABLE 4
Thermal Cycling Tests

| | CNT | Temperature | | No. of | Debonding | Debonding |
|---|---|---|---|---|---|---|
| Sample | ratio (%) | Range | Soak Time | Cycles | Temperature | Time |
| 1 | 0.7 | −50° C.~25° C. | 5 min | 20 | 71.5° C. | 5 min |
| 2 | 0.7 | −50° C.~25° C. | 5 min | 50 | 72.8° C. | 5 min |
| 3 | 0.5 | −50° C.~25° C. | 1 min | 80 | 115.2° C. | 10 min |
| 4 | 0.7 | −50° C.~25° C. | 2 min | 100 | 70.5° C. | 5 min |

### Electrical Tests

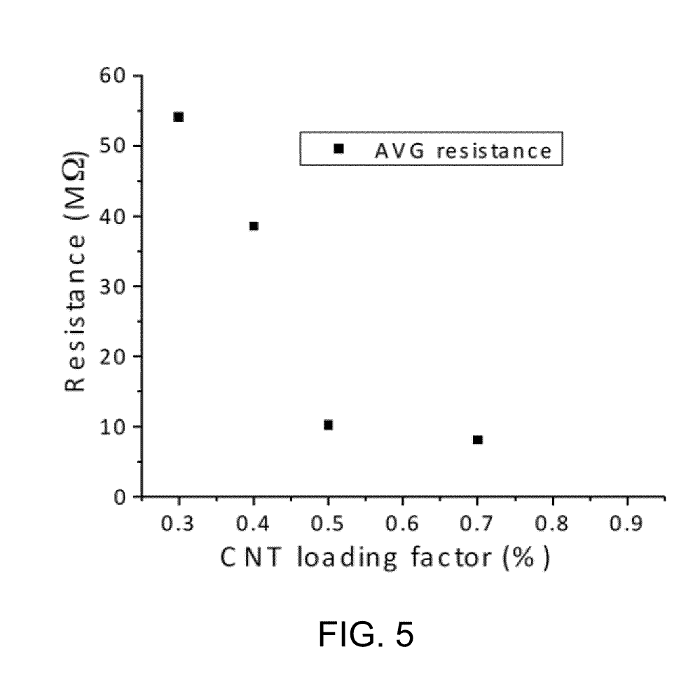

FIG. 5 shows schematically the relationship of an average resistance to CNT loading factor of reworkable epoxy bonding composites according to certain embodiments of the present invention. Data of the average resistance as shown in FIG. 5 is obtained by the statistical data acquired in the electrical tests, which is listed in Tables 5 and 6. Data of the resistance listed as “open” means the sample being electrically insulated. The electrical tests are performed for the purposes of checking continuity on cured epoxy samples using a high precision multimeter. As shown in FIG. 5 and Table 5, when the CNT loading factor increased, the electrical resistance decreased until the CNT loading factor reaches 0.7%.

TABLE 5
Thermal Reworkability Tests

| CNT loading factor (%) | Sample | Resistance (MΩ) |
|---|---|---|
| 0.1 | 1 | Open |
| 0.1 | 2 | Open |
| 0.1 | 3 | Open |
| 0.3 | 1 | 55.4 |
| 0.3 | 2 | 54.5 |
| 0.3 | 3 | 52.2 |
| 0.5 | 1 | 9.8 |
| 0.5 | 2 | 8.4 |
| 0.5 | 3 | 12.2 |
| 0.4 | 1 | 43.2 |
| 0.4 | 2 | 34.5 |
| 0.4 | 3 | 38 |
| 0.6 | 1 | Open |
| 0.6 | 2 | Open |
| 0.6 | 3 | Open |
| 0.7 | 1 | Open |
| 0.7 | 2 | Open |
| 0.7 | 3 | 8.12 |

TABLE 6
Reworkability Tests - set 2

| Pad No. | Resistance (Ω) | Pad # | Resistance (Ω) |
|---|---|---|---|
| 2-3 | Open | 22-79 | Open |
| 4-5 | Open | 23-78 | Open |
| 6-7 | Open | 24-77 | Open |
| 8-9 | Open | 25-76 | Open |
| 10-11 | Open | 26-75 | Open |
| 12-13 | Open | 27-74 | Open |
| 14-15 | Open | 28-73 | Open |
| 16-17 | Open | 29-72 | Open |
| 18-19 | Open | 30-71 | Open |
| 42-43 | Open | 31-70 | Open |
| 44-45 | Open | 32-69 | Open |
| 46-47 | Open | 33-68 | Open |
| 48-49 | Open | 34-67 | Open |
| 50-51 | Open | 35-66 | Open |
| 52-53 | Open | 36-65 | Open |
| 54-55 | Open | 37-64 | Open |
| 56-57 | Open | 38-63 | Open |
| 58-59 | Open | 39-62 | Open |

### Detachment and Inspection

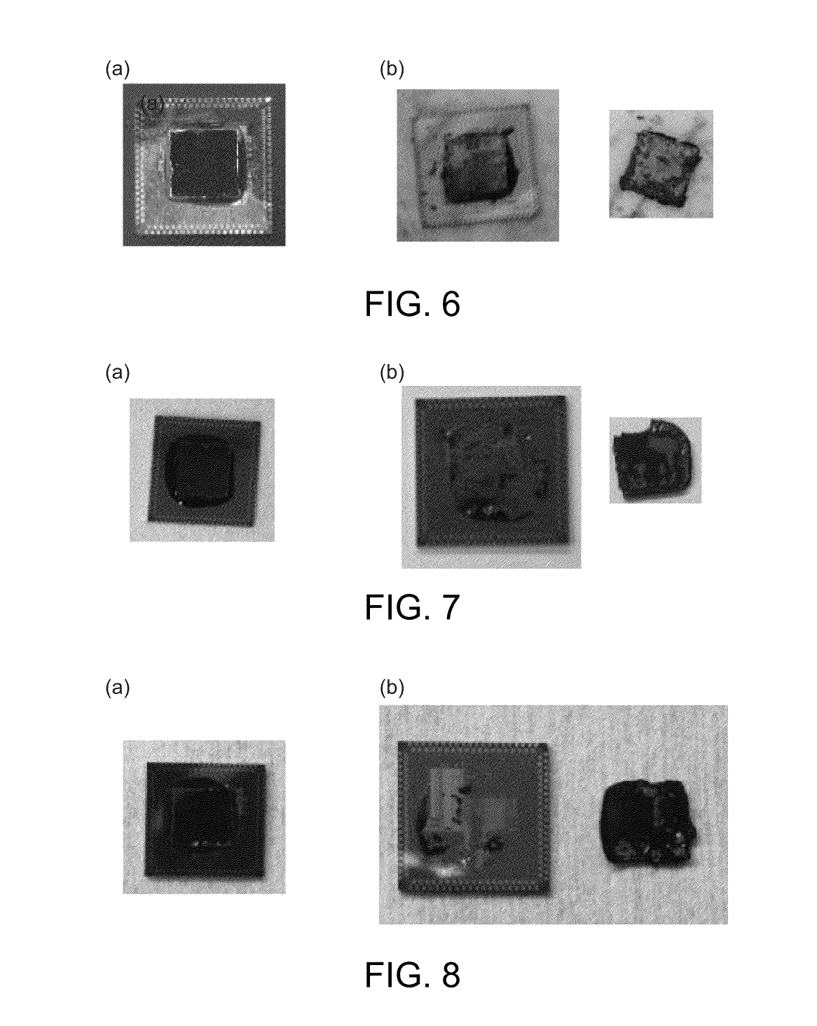

FIGS. 6-11 show schematically images of samples of bonded and debonded carriers and chips according to certain embodiments of the present invention. In each of the FIGS. 6-11, figure (a) shows an image of a sample of bonded carrier and chip, and figure (b) shows debonded images of the carrier (left) and the chip (right). The CNT loading factors of the reworkable epoxy bonding composite in each of the samples as shown in FIGS. 6-11 are listed in Table 7.

As shown in each of FIGS. 6-11, residue formation was observed on the chip as well as the carrier after detachment. Specifically, more residue accumulation is formed on the chip compared to the carrier, particularly as shown in FIG. 11.

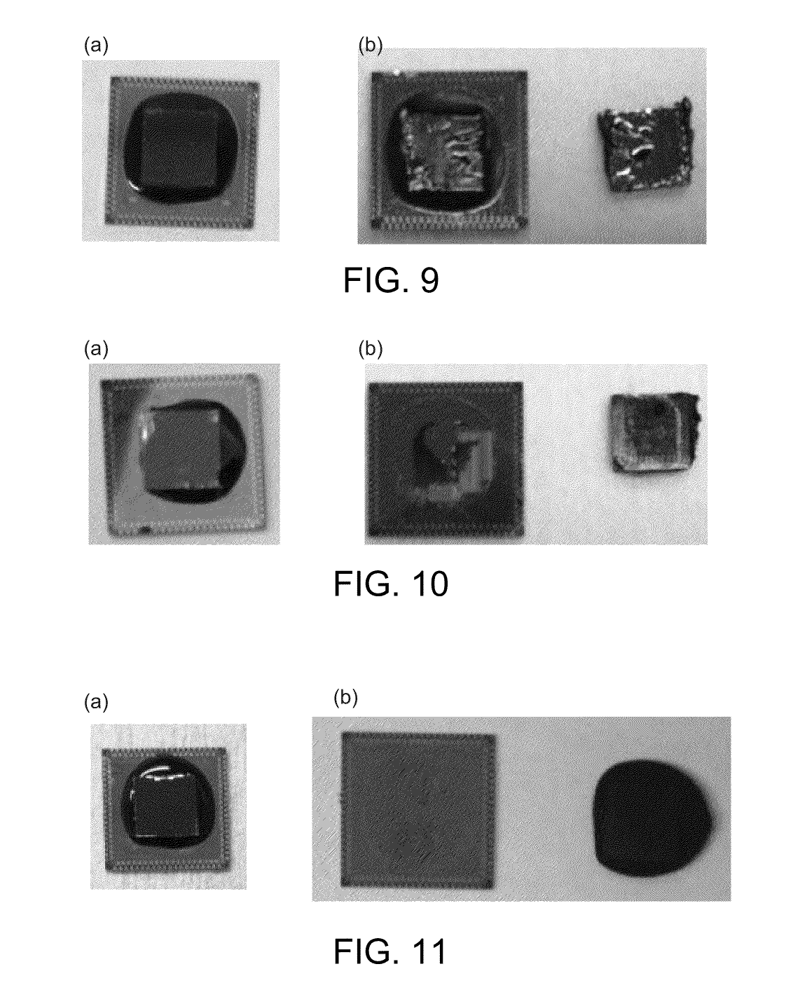

TABLE 7
Detachment and Inspection Tests

| | CNT ratio | | CNT ratio | | CNT ratio |
|---|---|---|---|---|---|
| FIG. | (%) | FIG. | (%) | FIG. | (%) |
| FIG. 6 | 0.1 | FIG. 7 | 0.3 | FIG. 8 | 0.5 |
| FIG. 9 | 0.4 | FIG. 10 | 0.6 | FIG. 11 | 0.7 |

### Cleaning Protocols

Ultrasonic cleaning is a process to convert electrical energy to high frequency mechanical wave. During the ultrasonic process, microscopic level of nucleus growth and collapse occur and followed by implosion, thus creating enough energy to clean surface without damaging the components to be cleaned. An example of the ultrasonic cleaning process utilizes piezoelectric transducers to generate high frequency alternating waves, resulting in the liquid under compression and tension, and forming nuclei and cavitation bubbles; then the cavitation bubbles grow and collapse thus conducting surface/component cleaning.

Certain embodiments of the cleaning procedure have been described with respect to the flowchart as shown in FIG. 1C. A plurality of cleaning protocols is provided with the following steps.

### Protocol 1: 0.3% and 0.5% CNT Ratios

The detached chip and the detached carrier of the sample is performed with (1) ultrasonication in Dynasolve for 24 hours, and then through (2) surface cleaning in acetone and IPA.

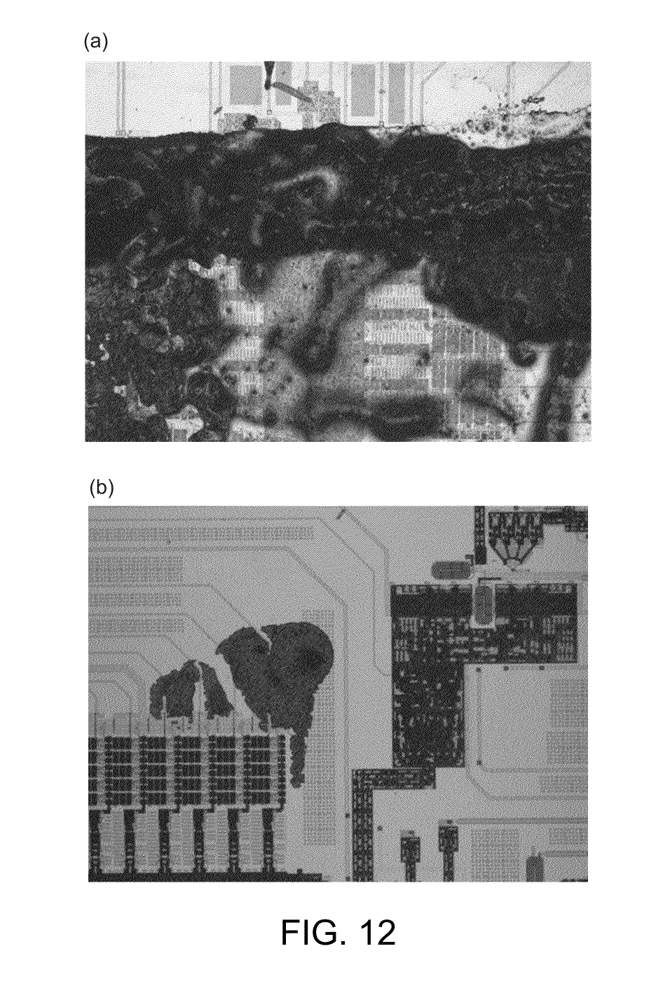

FIG. 12 shows schematically (a) an image of a detached carrier and chip sample before performing the cleaning protocol 1 and (b) an image of the detached carrier and chip sample after performing the cleaning protocol 1 according to certain embodiments of the present invention. As shown in FIG. 12, residue accumulation was observed on the surfaces of the carrier and the chip. Mapping of the residue confirmed higher accumulation in the central area of the carrier compared to the edges and corners.

### Protocol 2: 0.7% CNT Ratio

The detached chip and the detached carrier of the sample is performed with (1) ultrasonication in Dynasolve for 24 hours, and then (2) ultrasonication in acetone for 24-48 hours, and then through (3) surface cleaning in acetone and IPA.

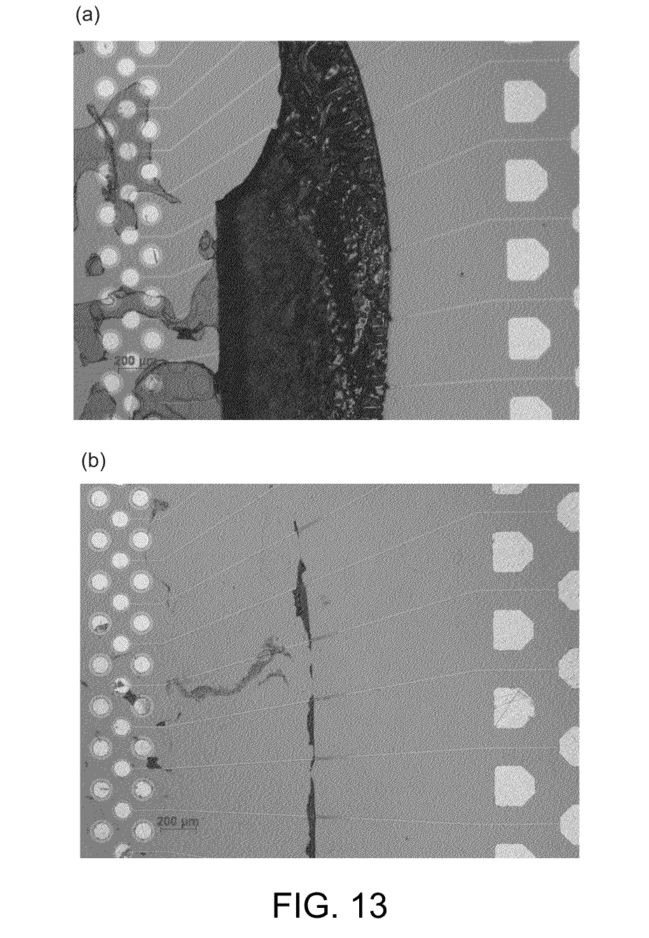

FIG. 13 shows schematically (a) an image of a detached carrier and chip sample before performing the cleaning protocol 2 and (b) an image of the detached carrier and chip sample after performing the cleaning protocol 2 according to certain embodiments of the present invention. As shown in FIG. 13, mapping of the residue confirmed accumulation in the areas near the edges of the attached chip. Comparing to the Protocol 1, the residue accumulation as shown in FIG. 13(b) is reduced on the surfaces of the carrier and the chip.

### Protocol 3: 0.6% and 0.7% CNT Ratios

The detached chip and the detached carrier of the sample is performed with (1) ultrasonication in acetone for 48 hours, and then (2) ultrasonication in Dynasolve for 48-72 hours, and then through (3) surface cleaning in acetone and IPA.

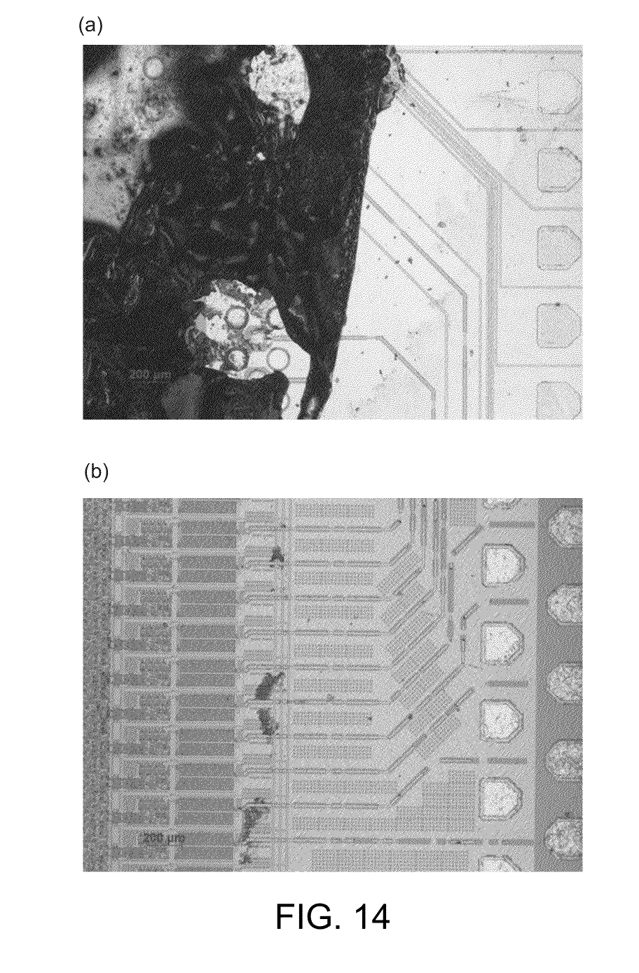

FIG. 14 shows schematically (a) an image of a detached carrier and chip sample before performing the cleaning protocol 3 and (b) an image of the detached carrier and chip sample after performing the cleaning protocol 3 according to certain embodiments of the present invention. The residue accumulation as shown in FIG. 14(b) is further reduced on the surfaces of the carrier and the chip comparing to the Protocols 1 and 2.

As discussed above, the inventors have provided the test results to show the properties, such as reworkability, thermal conductivity and electrical resistance, of the reworkable epoxy bonding composite. In certain embodiments, the reworkable epoxy bonding composite may be used in a superconductor multi-chip module, which includes the carrier and a plurality of chips, as the adhesive layer between each of the chips and the carrier. The properties of the reworkable epoxy bonding composite ensures the superconductor multi-chip module to have desirable reworkability, thermal conductivity and electrical resistance.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments were chosen and described in order to explain the principles of the invention and their practical application so as to enable others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

### REFERENCE LIST

[1] Gupta, Deepnarayan, Kadin, Alan M., Mukhanov, Oleg A., Rosa, Jack, and Nicholson, David, “Benefits of Superconductor Digital-RF Transceiver Technology to Future Wireless Systems”, Proceedings of SDR Technical Conference, vol. 1, November 2002, pp 221-226.
[2] Mukhanov, Oleg A., Gupta, Deepnarayan, Kadin, Alan M., and Semenov, Vasili K., “Superconductor analog-to-digital converters”, Proceedings of the IEEE, vol. 92, October 2004, pp 1564-1584.
[3] Zhou, W, Ooi, Y, Russo, R, Papanek, P, Luzzi, D, Fischer, J, Bronikowski, M, Willis, P and Smalley, R, “Structural Characterization and Diameter-Dependent Oxidative Stability of Single Walled Carbon Nanotubes Synthesized by the Catalytic Decomposition of CO,” Chem. Physics. Letts., vol. 350, (2001), pp. 6-

What is claimed is:

1. A method of applying a reworkable, thermally conductive and electrically resistive material as a bonding structure in a module with a carrier and at least one chip, comprising:
(a) purifying an anisotropic structure;
(b) dispersing the purified anisotropic structure in a solvent to form a mixture;
(c) adding an epoxy resin in the mixture to form an anisotropic structure-epoxy solution;
(d) forming a homogeneous mixture by heating and stirring the anisotropic structure-epoxy solution for a first time period to evaporate the solvent;
(e) cooling the homogeneous mixture at room temperature for a second time period, and adding a hardener in the cooled homogeneous mixture to form a homogeneous solution;
(f) applying the homogeneous solution between the carrier and the chip of the module, and curing the homogeneous solution at a curing temperature for a curing time period to form a reworkable epoxy bonding layer between the carrier and the chip such that the chip is attached to the carrier by the reworkable epoxy bonding layer, wherein an anisotropic structure loading factor of the reworkable epoxy bonding layer is about 0.1%-1.0% such that the reworkable epoxy bonding layer is thermally conductive and electrically resistive, and wherein the reworkable epoxy bonding layer is configured to debond at a debonding temperature for a debonding time period such that the chip is detachable from the carrier; and
(g) when the chip is identified as a faulty chip, detaching the faulty chip from the carrier by heating the module at the debonding temperature for the debonding time period, and performing a cleaning procedure to the detached chip and the detached carrier to reduce residues of the reworkable epoxy bonding layer on the detached chip and the detached carrier, such that a replacement chip is attachable to the carrier to replace the faulty chip, wherein the debonding temperature is about 63-170° C., and the debonding time period is about 1-25 minutes.

2. The method of claim 1, wherein the anisotropic structure comprises carbon nanotubes (CNTs).

3. The method of claim 2, wherein the CNTs are single-wall CNTs (SWCNTs).

4. The method of claim 3, wherein the first time period is about 3-5 hours, the second time period is about 1.5-2.5 hours, the curing temperature is a room temperature, and the curing time period is about 20-28 hours.

5. The method of claim 3, wherein the anisotropic structure loading factor of the reworkable epoxy bonding layer is about 0.6%-0.9%, the debonding temperature is about 65-90° C., and the debonding time period is about 1-6 minutes.

6. The method of claim 3, wherein the anisotropic structure loading factor of the reworkable epoxy bonding layer is about 0.3%-0.5%, the debonding temperature is about 105-155° C., and the debonding time period is about 1-12 minutes.

7. The method of claim 1, wherein the anisotropic structure comprises a two dimensional (2D) anisotropic structure.

8. The method of claim 7, wherein the 2D anisotropic structure comprises graphene.

9. The method of claim 1, wherein the cleaning procedure comprises:
ultrasonicating the detached chip and the detached carrier in an acrylic remover for a third time period; and
surface cleaning the detached chip and the detached carrier with acetone and isopropanol.

10. The method of claim 9, wherein the acrylic remover is Dynasolve.

11. The method of claim 9, wherein the cleaning procedure further comprises:
ultrasonicating the detached chip and the detached carrier in acetone for a fourth time period.

12. The method of claim 11, wherein the third time period is about 24-72 hours, and the fourth time period is about 24-48 hours.

13. The method of claim 1, wherein the module is a superconductor multi-chip module.

14. The method of claim 13, wherein the superconductor multi-chip module comprises the carrier and a plurality of chips, wherein each of the plurality of chips is configured to be attached to the carrier by a corresponding layer of the reworkable epoxy bonding layer.

15. A reworkable module formed by the method of claim 1.

16. The reworkable module of claim 15, being a superconductor multi-chip module comprising the carrier and a plurality of chips, wherein each of the plurality of chips is configured to be attached to the carrier by a corresponding layer of the reworkable epoxy bonding layer.

17. A method of applying a reworkable, thermally conductive and electrically resistive material as a bonding structure in a module with a carrier and at least one chip, comprising:
(i) preparing a homogeneous solution with an anisotropic structure and an epoxy resin;
(ii) applying the homogeneous solution between the carrier and the chip of the module, and curing the homogeneous solution at a curing temperature for a curing time period to form a reworkable epoxy bonding layer between the carrier and the chip such that the chip is attached to the carrier by the reworkable epoxy bonding layer, wherein an anisotropic structure loading factor of the reworkable epoxy bonding layer is about 0.1%-1.0% such that the reworkable epoxy bonding layer is thermally conductive and electrically resistive, and wherein the reworkable epoxy bonding layer is configured to debond at a debonding temperature for a debonding time period such that the chip is detachable from the carrier; and
(iii) when the chip is identified as a faulty chip, detaching the faulty chip from the carrier by heating the module at the debonding temperature for the debonding time period, such that a replacement chip is attachable to the carrier to replace the faulty chip.

18. The method of claim 17, wherein the step of preparing a homogeneous solution comprises:
(a) purifying the anisotropic structure;
(b) dispersing the purified anisotropic structure in a solvent to form a mixture;
(c) adding the epoxy resin in the mixture to form an anisotropic structure-epoxy solution;
(d) forming a homogeneous mixture by heating and stirring the anisotropic structure-epoxy solution for a first time period to evaporate the solvent; and
(e) cooling the homogeneous mixture at room temperature for a second time period, and adding a hardener in the cooled homogeneous mixture to form the homogeneous solution.

19. The method of claim 18, wherein the anisotropic structure comprises carbon nanotubes (CNTs).

20. The method of claim 19, wherein the CNTs are single-wall CNTs (SWCNTs).

21. The method of claim 20, wherein the first time period is about 3-5 hours, and the second time period is about 1.5-2.5 hours.

22. The method of claim 20, wherein the curing temperature is a room temperature, and the curing time period is about 20-28 hours.

23. The method of claim 17, wherein the anisotropic structure comprises a two dimensional (2D) anisotropic structure.

24. The method of claim 23, wherein the 2D anisotropic structure comprises graphene.

25. The method of claim 17, wherein the debonding temperature is about 63-170° C., and the debonding time period is about 1-25 minutes.

26. The method of claim 17, wherein the anisotropic structure loading factor of the reworkable epoxy bonding layer is about 0.6%-0.9%, the debonding temperature is about 65-90° C., and the debonding time period is about 1-6 minutes.

27. The method of claim 17, wherein the anisotropic structure loading factor of the reworkable epoxy bonding layer is about 0.3%-0.5%, the debonding temperature is about 105-155° C., and the debonding time period is about 1-12 minutes.

28. The method of claim 17, wherein the step of detaching the faulty chip when the chip is identified as the faulty chip further comprises:
performing a cleaning procedure to the detached chip and the detached carrier to reduce residues of the reworkable epoxy bonding layer on the detached chip and the detached carrier.

29. The method of claim 28, wherein the cleaning procedure comprises:
ultrasonicating the detached chip and the detached carrier in an acrylic remover for a third time period; and
surface cleaning the detached chip and the detached carrier with acetone and isopropanol.

30. The method of claim 29, wherein the acrylic remover is Dynasolve.

31. The method of claim 29, wherein the cleaning procedure further comprises:
ultrasonicating the detached chip and the detached carrier in acetone for a fourth time period.

32. The method of claim 31, wherein the third time period is about 24-72 hours, and the fourth time period is about 24-48 hours.

33. The method of claim 17, wherein the module is a superconductor multi-chip module comprising the carrier and a plurality of chips, wherein each of the plurality of chips is configured to be attached to the carrier by a corresponding layer of the reworkable epoxy bonding layer.

34. A reworkable module formed by the method of claim 17.

35. The reworkable module of claim 34, being a superconductor multi-chip module comprising the carrier and a plurality of chips, wherein each of the plurality of chips is configured to be attached to the carrier by a corresponding layer of the reworkable epoxy bonding layer.
